(19) United States
(12) Patent Application Publication
(10) Pub. No.: US 2026/0319540 A1
(43) Pub. Date: Oct. 15, 2026

(54) METHODS AND APPARATUS TO INCREASE PERFORMANCE OF A TRANSCEIVER

(71) Applicant: Texas Instruments Incorporated, Dallas, TX (US)

(72) Inventors: Shlok Vaibhav Singh, Bengaluru (IN); Deep Banerjee, Bangalore (IN); Lokesh Kumar Gupta, Bangalore (IN); Shishir Goyal, Bangalore (IN); Vikas Kumar Thawani, Bengaluru (IN)

(21) Appl. No.: 19/552,574

(22) Filed: Feb. 27, 2026

(30) Foreign Application Priority Data
Apr. 9, 2025 (IN) 202541034728

(51) Int. Cl. G05F 3/26; H03K 17/16

(52) U.S. Cl. CPC G05F 3/26; H03K 17/16

(57) ABSTRACT

An example apparatus includes: a first diode configured to, when conducting, pass a first diode current from an input terminal of the first diode to an output terminal of the first diode, the first diode current including a first leakage current of the first diode; a second diode configured to, when conducting, pass a second diode current from an input terminal of the second diode to an output terminal of the second diode, the second diode current including a second leakage current of the second diode, the second diode current corresponding to the first diode current; a current source configured to generate a steady state current corresponding to the first diode current at steady state; and a current mirror configured to compensate for the first leakage current based on the second leakage current.

### CROSS-REFERENCE TO RELATED APPLICATION

This application claims the benefit of and priority to Indian Provisional Patent Application No. 202541034728, filed Apr. 9, 2025, which is hereby incorporated herein by reference in its entirety.

### TECHNICAL FIELD

This description relates generally to an electronic system and method, and, in particular embodiments, to methods and apparatus to increase performance of a transceiver.

### BACKGROUND

In some systems, devices and/or nodes include transceivers to communicate (e.g., send or receive data) with each other via an interface (e.g., an Ethernet connection, a control area network-based bus (CAN bus) connection, and/or any other differential connection). For example, different devices in a vehicle system may communicate information to a controller via a shared Ethernet and/or control area network (CAN) bus interface/connection. Such systems require a protocol to enable each device to have the ability to transmit information without another device transmitting information via the same shared interface. For example, a CAN-based protocol (e.g., a CAN-XL protocol) includes two modes of operation. The first mode is a signal improvement capability (SIC) mode, where the differential voltage is either a high voltage or a zero voltage and the second mode is a data mode, where the differential voltage is a positive voltage or a negative voltage. SIC mode is a specialized transceiver technology that removes signal glitches (e.g., ringing) that occur at high speeds, allowing for higher bit rates and CAN arbitration. Data mode sends data at higher speeds than SIC mode. However, because the bus is driven in both phases, CAN arbitration is not supported.

### SUMMARY

In accordance with an embodiment, a circuit includes a transistor having a first terminal, a first diode having an input terminal and an output terminal, the input terminal of the first diode coupled to the first terminal of the transistor, the first diode configured to, when conducting, pass a first diode current from the input terminal of the first diode to the output terminal of the first diode, the first diode current includes a first leakage current of the first diode, a second diode having an input terminal and an output terminal, the second diode configured to, when conducting, pass a second diode current from the input terminal of the second diode to the output terminal of the second diode, the second diode current includes a second leakage current of the second diode, the second diode current corresponding to the first diode current, a current source having an input terminal coupled to the output terminal of the second diode, the current source configured to generate a steady state current corresponding to the first diode current at steady state, and a current mirror having a first terminal and a second terminal, the first terminal of the current mirror coupled to the output terminal of the second diode and the input terminal of the current source, the second terminal of the current mirror coupled to the input terminal of the first diode, the current mirror configured to compensate for the first leakage current based on the second leakage current.

In accordance with an embodiment, a circuit includes a first comparator circuit having an output terminal, the first comparator circuit configured to generate a first output voltage based on a differential voltage on a differential connection, the first output voltage being a first voltage based on the differential voltage being greater than a first threshold, the first output voltage being a second voltage based on the differential voltage being less than a second threshold, a second comparator circuit having an output terminal, the second comparator circuit configured to generate a second output voltage based on the differential voltage, the second output voltage being a third voltage based on the differential voltage being greater than a third threshold different than the first and second thresholds, a delay circuit having an input terminal and an output terminal, the input terminal of the delay circuit coupled to the output terminal of the second comparator circuit, coupled to the second comparator circuit, the delay circuit configured to pulse a select signal to a high voltage for a duration of time based on the second output voltage becoming the third voltage, and a multiplexer having a first input terminal, a second input terminal, and a select terminal, the first input terminal of the multiplexer coupled to a supply voltage terminal, the second input terminal of the multiplexer coupled to the output terminal of the first comparator circuit, and the select terminal of the multiplexer coupled to the output terminal of the delay circuit, the multiplexer configured to mask the first output voltage of the first comparator circuit based on the select signal being the high voltage, and output the first output voltage of the first comparator circuit based on the select signal being a low voltage.

In accordance with an embodiment, a method includes passing a first diode current from an input terminal of a first diode to an output terminal of the first diode, the first diode current includes a first leakage current of the first diode, passing a second diode current from an input terminal of the second diode to an output terminal of the second diode, the second diode current includes a second leakage current of the second diode, the second diode current corresponding to the first diode current, generating a steady state current corresponding to the first diode current at steady state, and compensating for the first leakage current based on a difference between the second leakage current and the steady state current.

In accordance with an embodiment, a method includes generating a first output voltage based on a differential voltage on a differential connection, the first output voltage being a first voltage based on the differential voltage being greater than a first threshold, the first output voltage being a second voltage based on the differential voltage being less than a second threshold, generating a second output voltage based on the differential voltage, the second output voltage being a third voltage based on the differential voltage being greater than a third threshold different than the first and second thresholds, pulsing a select signal to a high voltage for a duration of time based on the second output voltage becoming the third voltage, masking the first output voltage based on the select signal being the high voltage, and outputting the first output voltage based on the select signal being a low voltage.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an example system device to improve performance of a transceiver, according to an embodiment of the present disclosure;

FIGS. 2A-2B are circuit implementations of a driver of FIG. 1, according to embodiments of the present disclosure;

FIG. 3 is a circuit implementation of a leakage current compensation circuit of FIGS. 2A-2B, according to an embodiment of the present disclosure;

FIG. 4A is a timing diagram illustrating current into and out of a diode in a driver without leakage current compensation;

FIG. 4B is a timing diagram illustrating leakage compensation current generated by the leakage current compensation circuit of FIG. 3, according to an embodiment of the present disclosure;

FIG. 5 illustrates a comparison of common mode mismatch between a driver without leakage current compensation and the driver of FIGS. 2A-2B, according to an embodiment of the present disclosure;

FIG. 6 is a circuit implementation of a differential voltage comparator circuit of FIG. 1, according to an embodiment of the present disclosure;

FIG. 7A is a timing diagram illustrating a differential voltage based on two different modes of operation;

FIG. 7B is a timing diagram illustrating a glitch that occurs without the differential voltage comparator circuit of FIG. 6;

FIG. 8A is a timing diagram illustrating a comparison of a receiver without glitch protection with the differential voltage comparator circuit of FIG. 6, according to an embodiment of the present disclosure;

FIGS. 8B and 8C are timing diagrams illustrating differential voltage in conjunction with the differential voltage comparator circuit of FIG. 6, according to an embodiment of the present disclosure;

FIG. 9 is a flowchart of a method of controlling the differential voltage comparator circuit of FIG. 6, according to an embodiment of the present disclosure;

FIG. 10 is a block diagram of an example processing platform including programmable circuitry structured to execute, instantiate, or perform the example machine-readable instructions or perform the example operations of FIG. 9 to implement the differential voltage comparator circuit of FIG. 6; and

FIG. 11 is an example system implementing the device of FIG. 1, according to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be received without one or more of the specific details, or with other methods, components, materials, and the like. In some cases, known structures, materials, or operations are not shown or described in detail so as not to obscure the different aspects of the embodiments. References to “an embodiment” or “an example” in this description indicate that a particular configuration, structure, or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Embodiments of the present disclosure are described in specific contexts, for example, a vehicular system connected via a CAN-based (e.g., Classical CAN, CAN flexible data rate (FD), CAN SIC, CAN-XL, etc.) interface. Some embodiments may be used in other applications or systems, such as Ethernet systems, high-definition multimedia interface (HDMI) systems, Bluetooth systems, Wi-Fi systems, Inter-Integrated Circuit (I2C) systems, Serial Peripheral Interface (SPI) systems, FireWire systems, and/or any other system that utilizes a differential interface between two or more devices.

In an embodiment, a circuit is disclosed to implement a circuit to compensate for leakage current from a diode in a driver of the transmitter circuit, thereby minimizing common mode mismatch and reducing noise and emissions (e.g., radio frequency noise and emissions). In another embodiment, a circuit is disclosed to avoid glitches in the received data (RCD) connection in SIC mode due to out of bound protection circuit(s) responding to negative undershoots on the shared interface due to ringing.

Some systems include multiple devices or nodes that communicate data to/from one or more other devices and/or nodes within the system via a differential interface/connection/bus (e.g., a CAN-based connection, an Ethernet based connection, etc.). In such a network, a device can control the voltages on the two wires of the differential interface/connection/bus to convey data. For example, in some modes (e.g., slow or SIC modes), a device can output a high voltage (e.g., 3.5 V) on the high connection (e.g., CANH) of the differential interface/connection/bus and transmit a low voltage (e.g., 1.5 V) on the low connection (e.g., CANL) of the differential interface/connection/bus to signify a logical zero. Additionally, the device can output a low voltage (e.g., 2.5 V) on both the high wire and the low wire to signify a logical one. In general, in slow or SIC modes, a voltage differential between CANH and CANL can range between 1.5 V and 3 V. In other modes (e.g., fast or data modes), a device can output a first voltage (e.g., 3 V) on the high wire (e.g., CANH) of the differential interface/connection/bus and transmit a second voltage (e.g., 2 V) on the low wire (e.g., CANL) of the differential interface/connection/bus to generate a voltage differential (VOD) of +1 V (3V-2V), signifying a logical zero. Additionally, the device can output a third voltage (e.g., 2 V) on the high wire and a fourth voltage (e.g., 3 V) on the low wire to generate a voltage differential (VOD) of −1V (2 V-3V), signifying a logical one. In general, in fast or data modes, a magnitude of a voltage differential between CANH and CANL can range between 0.6 V and 1.5 V.

Such devices utilize a driver to output the appropriate voltage to the high wire and low wire connections. Some drivers include high voltage diodes to block reverse current into a supply terminal or from a ground terminal to prevent bus lines getting shorted to a battery. However, high voltage diodes can have a leaky substrate terminal that can pull a small amount of current (e.g., leakage current) to ground via a substrate terminal. Thus, after a diode starts conducting (e.g., after current has been applied to the anode of the diode), a lower amount of current is output from the cathode of the diode. For example, if 20 milliamps (mA) are applied to the anode of the diode, only 18 mA may be output from the cathode of the diode, where 2 mA of leakage current drains from the substrate terminal of the diode. The leakage current has a time constant that causes the leakage current to vary with time. For example, when the diode first starts conducting, the leakage current is minimal and increases with time until it levels out to a steady state leakage current. Thus, after a transition from a diode not conducting to a diode conducting, the initial current through the diode is higher and gradually decreases until reaching a steady state current. Additionally, after the diode transitions from conducting to not conducting, a connection between the differential wires (e.g., CANH and CANL) temporarily draws current from the substrate connection of the diode, thereby causing the current at the cathode of the diode to go negative and then gradually increase until levelling off at zero current (e.g., due to the time constant of the leakage current). The change in the leakage current with time corresponds to a memory effect of the diode (e.g., the effect of the transition on the current is reflected in the output of the diode for a duration of time).

Due to the time constant associated with the leakage current, the current output from the cathode of the diode spikes during transitions, which causes a capacitor coupled between the differential wires and ground to charge or discharge during transitions which creates common mode voltage mismatches during transitions. Common mode mismatch can be represented as a ratio of the sum of the voltages on the differential wires (CANH+CANL) to the sum of the steady state voltage on the differential wires (CANH_{REC}+CANL_{REC}), the further away the ratio is from 1 at any point in time, the higher the common mode mismatch. The higher the common mode mismatch, the higher the emissions of the driver. Accordingly, examples disclosed herein provide a circuit to compensate for the leakage current of a high voltage diode with respect to the time constant of the leakage current to minimize common mode mismatch, emissions, and the memory effect of the diode.

As described above, during SIC mode, the differential voltage (VOD) between the high wire (CANH) and the low wire (CANL) is either a high voltage (e.g., 2 V) or a low voltage (e.g., 0 V) and, during fast mode, the differential voltage between the high wire and the low wire is either a positive voltage (e.g., 1 V) or a negative voltage (e.g., −1 V). To determine if a differential interface is idle or busy in SIC mode, a receiver compares the differential voltage to two thresholds (e.g., a high SIC-RX threshold (e.g., 900 mV) and a low SIC-RX threshold (e.g., 500 mV)). Thus, if the receiver determines that the differential signal is above the high SIC-RX threshold, the comparator outputs a first voltage (e.g., a logic low voltage). If the receiver determines that the differential signal is below the low SIC-RX threshold, the comparator outputs a second voltage (e.g., a logic high voltage). Likewise, to determine if a differential interface is idle or busy in fast/data mode, a receiver compares the differential voltage to two thresholds (e.g., a high data threshold (e.g., −250 mV) and a low data threshold (e.g., −450 mV)). Thus, if the receiver determines that the differential signal is above the high data threshold, the comparator outputs a first voltage (e.g., a logic high voltage). If the receiver determines that the differential signal is below the low data threshold, the comparator outputs a second voltage (e.g., a logic low voltage).

However, when a device is onboarded onto a network, or awakes from a sleep mode, the device is configured to initiate operation in SIC/slow mode and the SIC thresholds are set for determining whether the differential interface/bus/connection is idle or busy. However, if the system is operating in fast/data mode, then the receiver of the device in SIC mode will not be able to identify that the differential interface/connection/bus is busy. For example, because the high threshold of SIC mode may be higher than the maximum differential voltage on the differential interface/connection/bus when in fast/data mode, the output of the comparator will stay constant, corresponding to no activity. Thus, a controller may transmit data on the differential interface/connection/bus while another device is already sending data.

To solve the problem of system device operating in SIC mode while the rest of the system is in data mode, some systems utilize a logic AND gate to perform an AND function of the result of the comparison of the SIC based thresholds and the result of the data-based thresholds. Thus, during SIC operation, the output of the logic AND is based on the SIC thresholds (e.g., since the output of the fast threshold is a logic high during SIC operation). During data operation, the output of the logic AND is based on the data threshold (e.g., since the output of the SIC threshold is a logic high during data operation). Thus, the output of the logic AND gate (referred to herein as a receiver data (RXD) signal) will reflect activity on the differential interface/connection/bus regardless of whether the implementing device is in SIC mode or data mode.

Although the above logic AND-based solution works well in some scenarios, ringing and/or noise on the differential interface/connection/bus can cause glitches at the output of the logic AND gate, resulting in an inaccurate RXD signal being sent and processed by a controller. For example, when the system is operating in SIC mode, the differential voltage is supposed to be either high (e.g., 2 V) or low (e.g., 0 V) and the RXD output of the AND gate is controlled by the SIC thresholds, since the output of the fast threshold comparison should be a logic high during SIC operations (e.g., because the differential voltage should always be larger than the minimum data threshold). However, noise and/or ringing on the differential interface/connection/bus can, responsive to a transition from a high voltage to a low voltage on the differential interface/connection/bus, cause a negative differential voltage spike that is below the minimum data/fast threshold, thereby cause the AND logic to glitch and temporarily generate a logic low signal until the negative spike returns to above the maximum data/fast threshold. Examples disclosed herein provide a mechanism for blocking the data/fast threshold comparison to avoid the glitch without affecting normal operation of the receiver.

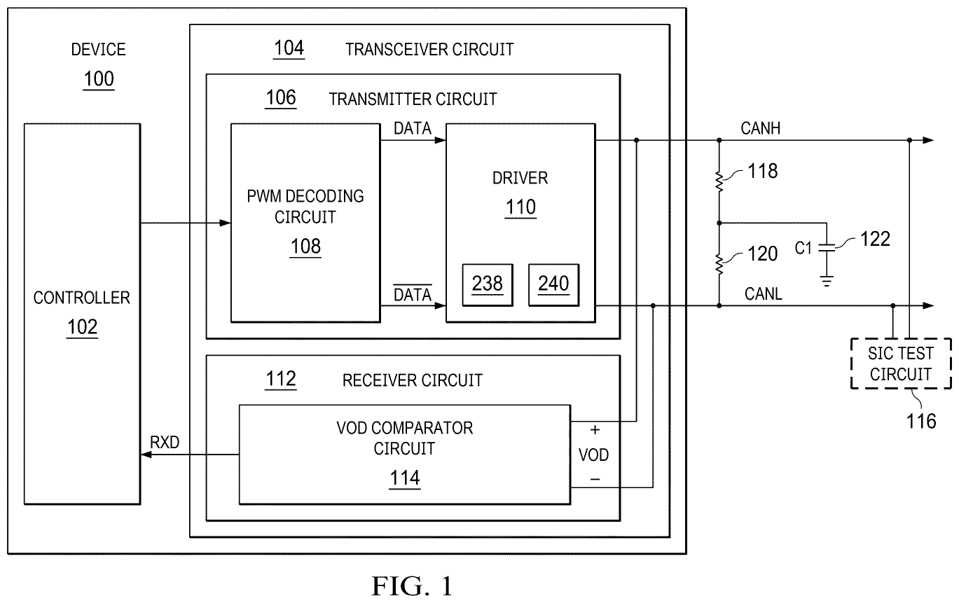

FIG. 1 is a block diagram implementation of device 100, according to an embodiment of the present disclosure. Device 100 includes controller 102, transceiver circuit 104, transmitter circuit 106, pulse width modulation decoding circuit 108, driver 110, receiver circuit 112, and voltage differential (VOD) comparator circuit 114. FIG. 1 further includes resistors 118, 120, capacitor 122, and SIC test circuit 116. Other implementations are also possible.

In normal operation, when controller 102 is to send data to another device via the differential interface/connection/bus (e.g., CANH and CANL connections), controller 102 outputs a pulse width modulated (PWM) signal to transmitter circuit 106 of transceiver circuit 104. The duty cycle of the PWM signal is based on whether controller 102 is outputting a one or a zero and/or based on whether operating in SIC mode or data mode. For example, controller 102 can output a PWM with a first duty cycle to cause driver 110 to output a positive voltage differential (e.g., CANH=3 V and CANL=2 V, 3 V-2 V=1 V) and output a PWM with a second duty cycle to cause driver 110 to output a negative voltage differential (e.g., CANH=2 V and CANL=3 V, 2 V-3 V=−1 V). PWM decoding circuit 108 generates a data signal and a data bar signal based on the PWM signal from controller 102. When data signal is high (e.g., a logic one) the data bar signal is low (e.g., a logic zero) and vice versa. The data and data bar signals are applied to gate of transistors/switches in driver 110 to control the transistors/switches to generate the corresponding voltage differential at the CANH and CANL connections.

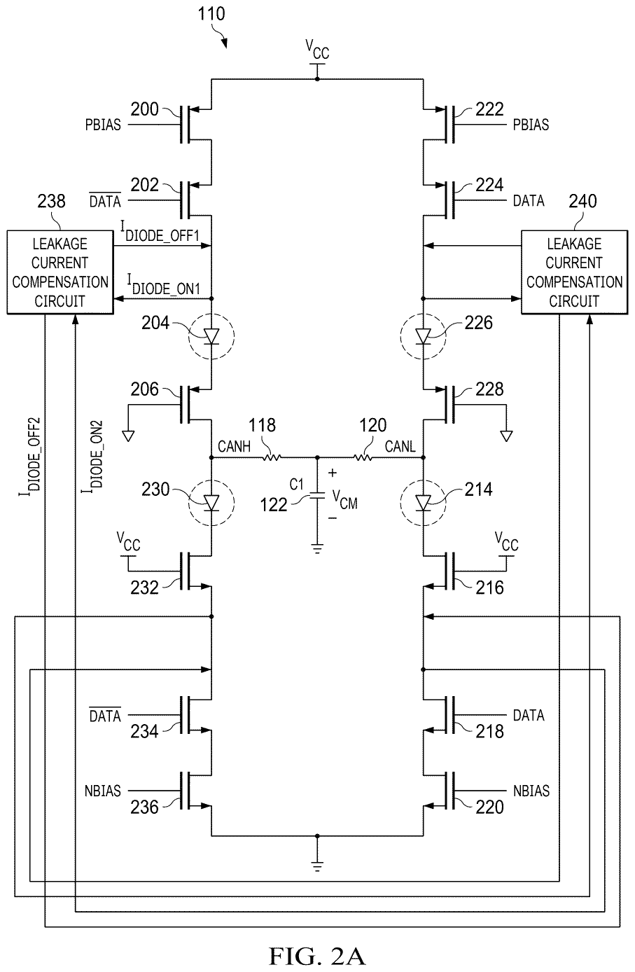

Driver 110 drives the voltages on the CANH and CANL connections to generate a differential voltage (VOD) based on the data and data bar signals. As further described below in conjunction with FIGS. 2A-2B, driver 110 includes high voltage diodes to prevent reverse current caused by voltage spikes on the CANH and/or CANL connections. However, the high voltage diodes of driver 110 create leakage current with a time constant. The variable leakage current can charge or discharge capacitor 122 during transitions, which creates common mode mismatch and increases emissions. Accordingly, driver 110 includes leakage current compensation circuits 238, 240 to compensate for the leakage current, thereby reducing common mode mismatch and reducing emissions. Driver 110 is further described below in conjunction with FIGS. 2A-2B.

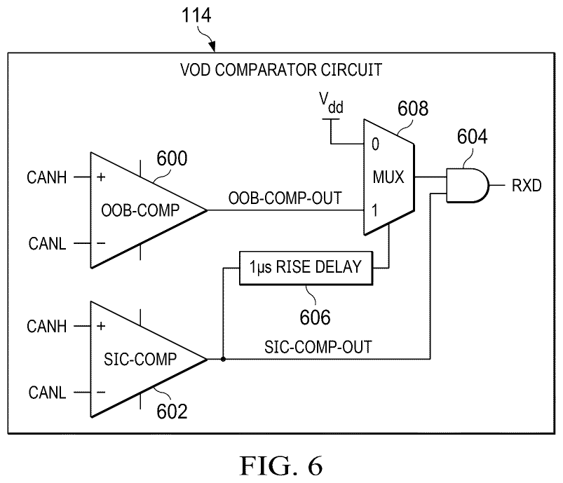

Receiver circuit 112 receives the voltage on the CANH connection and the voltage on the CANL connection. VOD comparator circuit 114 processes the CANH and CANL voltages to determine the logical data/state (e.g., dominant or recessive) corresponding to the received voltages by comparing the received differential voltage (e.g., CANH-CANL) to different thresholds. A dominant state occurs when the voltage on the CANH line goes high (e.g., 3.5 V) and the voltage on the CANL line goes low (1.5 V), creating a VOD greater than or equal to 0.9 V, indicating active transmission on the differential connections (e.g., the differential bus is busy). A recessive state occurs when the voltage on the CANH line and the CANL line are biased to a similar mid-level voltage (e.g., 2.5 V), creating a VOD near 0 V, indicating no active transmission on the differential connections (e.g., the differential bus is idle). Controller 102 processes the RXD output of VOD comparator circuit 114 to determine when it is okay to transmit data on the differential connection (e.g., when the RXD corresponds to a recessive or idle state). VOD comparator circuit 114 includes a first comparator circuit to determine if the VOD is above a maximum SIC threshold (e.g., corresponding to a logic zero/dominant state) or below a minimum SIC threshold (e.g., corresponding to a logic one/recessive state) for SIC/slow mode and a second comparator (e.g., an out of bound (OOB) comparator) to determine if the VOD is above a maximum data/fast threshold (e.g., corresponding to a logic zero) or below a minimum data/fast threshold (e.g., corresponding to a logic one) for data/fast mode. The results of the two comparisons are ANDed using a logic AND gate to generate the received data signal (RXD), which is provided to controller 102 to indicate whether the differential interface/connection/bus (e.g., CANH and CANL) is idle or busy. As described, the signals received through CANH and CANL can include noise and/or ringing. For purposes of illustration, FIG. 1 shows SIC test circuit 116 that can generate or simulate noise and/or ringing representative of actual noise and/or ringing that may be present on the CANH and/or CANL connections. The noise and/or ringing that occurs in the real world or through the SIC test circuit 116 can cause a glitch on the RXD signal due to a large negative VOD (e.g., caused by ringing) that temporarily and unintentionally satisfies the minimum data/fast threshold. As further described below in conjunction with FIG. 6, VOD comparator circuit 114 includes a circuit to mask the OOB comparator output for a duration of time to avoid the glitch. FIG. 1 also shows resistors 118, 120 and capacitor 122 that can be used to form RC filter(s). Though they are shown external to device 100, they may be implemented as part of device 100, e.g., included within driver 110.

FIG. 2A is an asymmetrical circuit implementation of driver 110 of FIG. 1, according to an embodiment of the present disclosure. Driver 110 includes transistors 200, 202, 206, 216, 218, 220, 222, 224, 228, 232, 234, 236, diodes 204, 214, 226, 230 and leakage current compensation circuits 238, 240. FIG. 2A also includes resistors 118, 120, and capacitor 122 of FIG. 1. Other implementations are also possible. FIG. 2A is asymmetrical, for example diode 230 and transistor 206 are coupled to resistor 118 and diode 214 and transistor 228 are coupled to resistor 120.

In operation, when PWM decoding circuit 108 outputs a logic high voltage for the data signal and a logic low voltage for the data bar signal, the voltages at the gate terminals of transistors 224, 218 are high voltages and the voltages at the gate terminals of transistors 202, 234 are low voltages. Thus, transistors 202, 218 close (e.g., enable, conduct, operate as a short) and transistors 224, 234 open (e.g., disable, do not conduct, operate as an open circuit). Accordingly, current will flow from VCC into the input/anode of diode 204 through the current path of transistors 200, 202, through the current path of transistor 206, from the CANH terminal to the CANL terminal through resistors 118, 120, into the input/anode of diode 214 and to ground via the current paths of transistors 216, 218, 220. Thus, the voltage at the CANH terminal is higher than the voltage at the CANL terminal corresponding to a positive voltage differential. As used herein, a current path is a path between the source and drain of a transistor.

When PWM decoding circuit 108 outputs a logic low voltage for the data signal and a logic high voltage for the data bar signal, the voltage at the gate terminals of transistors 202, 234 is a low voltage and the voltage at the gate terminals of transistors 224, 218 is a high voltage. Thus, transistors 224, 234 close (e.g., enable, conduct, operate as a short) and transistors 202, 218 open (e.g., disable, do not conduct, operate as an open circuit). Accordingly, current will flow from the supply voltage terminal (VCC) into the input/anode of diode 226 through the current path of transistors 222, 224, through the current path of transistor 228, from the CANL terminal to the CANH terminal through resistors 118, 120, into the input/anode of diode 230 and to ground via the current paths of transistors 232, 234, 220, 326 Thus, the voltage at the CANH terminal is lower than the voltage at the CANL terminal corresponding to a negative voltage differential.

Diodes 204, 214 226, 230, provide reverse current protection from any positive or negative voltage spikes on the CANH and/or CANL line that would otherwise intentionally cause current to flow into a supply terminal or from a ground terminal short to a battery, which could cause damage to the battery. However, each diode 204, 214, 226, 230 can cause a leakage current with a time constant. The leakage current is a small amount of current that is pulled from the anode toward ground through a substrate terminal of the corresponding diode. The time constant of the leakage current corresponds to an increase of leakage current responsive to a transition (e.g., from turn-on to turn-off of the diode or vice versa) until the leakage current levels to a steady state leakage current. Because of the time constant of the leakage current, the amount of current at the output of a diode changes after a transition. For example, after a transition from diode 204 not conducting (e.g., when transistor 202 is open) to diode 204 conducting (e.g., when transistor 202 is closed), all of the current into the anode of diode 204 is output through the cathode of diode 204, but the amount of current out of the cathode of diode 204 decreases with time until it reaches steady state. Thus, the amount of current through resistor 118 is initially higher during a transition and reduces until steady state is reached, which causes the common mode voltage (e.g., represented by the voltage across capacitor 122 (VCM) to be initially higher after a transition and then lower at steady state, resulting in an increase in common mode mismatch (e.g., (CANH+CANL)/(CANH_{REC}+CANL_{REC})), which increases emissions.

Additionally, after a transition from diode 204 conducting (e.g., when transistor 202 is closed) to diode 204 not conducting (e.g., when transistor 202 is open), the CANH bus pulls current from the cathode of the diode 204 via the leaky substrate terminal, thereby causing the capacitor 122 to discharge, pulling down the VCM voltage. Due to the time constant of the leaky substrate terminal, after a duration of time the negative current pulled from the substrate terminal will decrease to zero. Thus, the amount of current through resistor 118 is initially lower during a transition and reduces until steady state is reached, which causes the common mode voltage (e.g., represented by the voltage across capacitor 122 (VCM) to be initially lower after a transition and then lower at steady state, resulting in an increase in common mode mismatch (e.g., (CANH+CANL)/(CANH_{REC}+CANL_{REC})), which increases emissions.

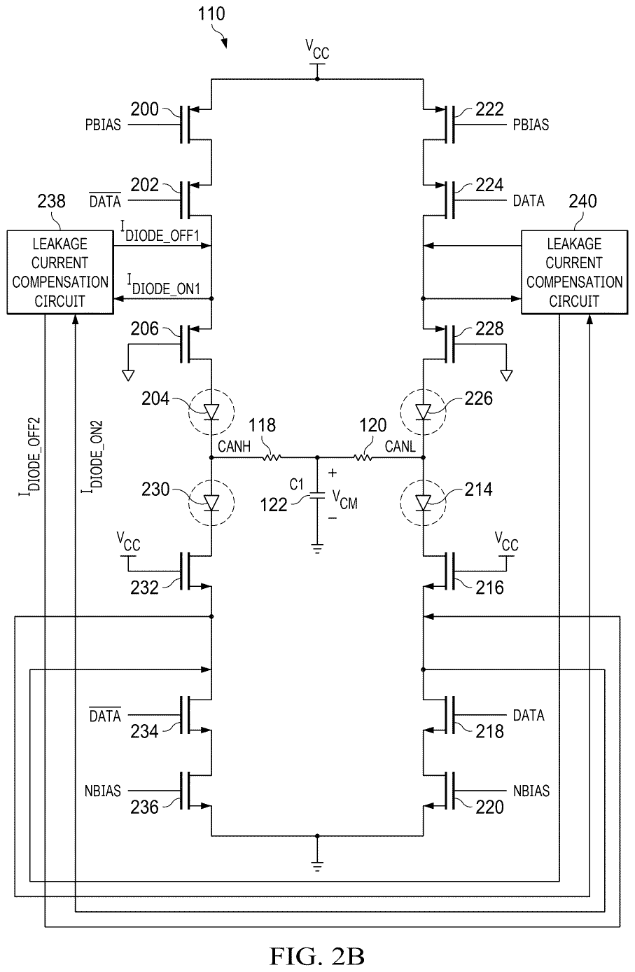

Leakage current compensation circuits 238, 240 compensate for the leakage current by pumping in a current or pulling out a current into particular nodes of driver 110. The current that is pumped in or pulled out is the same amount as the leakage current with the same time constant. For example, after a transition from not conducting to conducting, leakage current compensation circuit 238 pulls out a current from the anode of diode 204. The current that leakage current compensation circuit 238 pulls out is a difference between the current output by diode 204 minus the steady state current output by diode 204, as further described below in conjunction with FIG. 3. As the leakage current increases until it levels off to a steady state leakage current, the amount of current pulled out of the anode of diode 204 decreases until the amount of current pulled out is zero (e.g., when the leakage current reaches steady state). In this manner, instead of the output current of diode 204 initially peaking after a transition and then leveling out to a steady state output current, leakage current compensation circuit 238 causes the output current of diode 204 to remain substantially steady after a transition. Thus, the common mode voltage remains steady regardless of a transition and common mode mismatch is reduced and/or eliminated, thereby lowering emissions. Likewise, when diode 204 transitions from conducting to not conducting, current is pumped into anode of diode 204 to compensate for the current drawn from the substrate terminal by the CANH bus, thereby causing a steady voltage after a conducting to non-conducting transition. Leakage current compensation circuit 238 compensates for the leakage current and/or current drawn from substrate terminal for diodes 204, 214 and leakage current compensation circuit 240 compensates for the leakage current and/or current drawn from substrate terminal for diodes 226, 230. Leakage current compensation circuits 238, 240 are further described below in conjunction with FIG. 3.

In the example of FIG. 2A, the transistors 216, 218, 220, 232, 234, 236 are n-channel metal-oxide semiconductor field-effect transistors (MOSFETs), each with a gate terminal, a first drain terminal, and a second source terminal. Alternatively, transistors 216, 218, 220, 232, 234, 236 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 2A, the transistors 200, 202, 206, 222, 224, 228 are p-channel MOSFETs, each with a gate terminal, a first source terminal, and a second drain terminal. Alternatively, the transistors 200, 202, 206, 222, 224, 228 may be p-channel FETs, p-channel IGBTs, p-channel JFETs, PNP BJTs, or, with slight modifications, N-type equivalent devices. The gate terminal is an example of a control terminal and the source and drain terminals are examples of current path terminals. Additionally, a current path of a transistor corresponds to the path between the source and drain of a transistor.

FIG. 2B is a circuit implementation of driver 110 of FIG. 1, according to an embodiment of the present disclosure. Driver 110 in the embodiment of FIG. 2B shares substantially the same components as the embodiment of FIG. 2A. However, the embodiment of driver 110 in FIG. 2B is a symmetrical configuration. For example, the diodes 204, 230 are coupled to resistor 118 and diodes 214, 226 are coupled to resistor 120.

FIG. 3 is a circuit implementation of leakage current compensation circuit 238 of FIGS. 2A-2B, according to an embodiment of the present disclosure. FIG. 3 may illustrate the implementation of leakage current compensation circuit 240 of FIGS. 2A-2B. Leakage current compensation circuit 238 includes switches 302, 304, 306, diode 308, current source 310, and current mirrors 312, 314. Other implementations are also possible.

In operation, when the data signal from PWM decoding circuit 108 is high and the data bar from PWM decoding circuit 108 is low, switches 302, 304 are closed and switch 306 is open. Thus, current flows into the anode of diode 308, causing current to flow out from cathode of diode 308. Diode 308 may be a diode that is of the same size or substantially similar size as diodes 204, 214 or may be a scaled down version of diodes 204, 214. Thus, diode 308 has the same or substantially similar leakage current time constant as diodes 204, 214. Thus, the variable output current of diode 308 (e.g., which is initially higher after a transition and then decreases to a steady state current) reduces to steady state at the same rate as diodes 204, 214.

Current source 310 generates a current corresponding to the steady state current of diode 308. For example, after the leakage current of diode 308 settles to 18 mA when the input current is 20 mA (e.g., 2 mA lost to leakage current). Thus, current source 310 generates 18 mA of current corresponding to the settled 18 mA current of diode 308 when leakage current settles. The first terminal of current mirror 312 is coupled to the cathode of diode 308 and the input of current source 310. Thus, the current into the first terminal of current mirror 312 corresponds to a difference between the diode current output at the cathode of diode 308 and the current source current generated by current source 310.

When the diodes leakage current has reached steady state (e.g., after an amount of time after a transition, the amount of time corresponding to the time constant), the diode current from diode 308 is the same as the current source current from current source 310. Accordingly, no current enters the first terminal of current mirror 312. Thus, current mirror 312 does not mirror any current and no current is pulled from diodes 204, 214. Because the leakage current of diode 308 has the same time constant as the leakage current of diodes 204, 214, when diodes 204, 214 are in steady state, current mirror 312 does not pull current from diodes 204, 214.

However, during a transition (e.g., after switches 302, 304 and transistors 202, 218 close and switch 306 and transistors 224, 234 open), the leakage current has not had time to settle. Accordingly, the output diode current from diode 308 is initially higher than the current source current from current source 310 due to the settling time of the leakage current of diode 308. Thus, there will be an amount of current flowing into the first terminal of current mirror 312. The small amount of current is a difference between the diode current and the steady state current. Current mirror 312 mirrors and/or amplifies the current into the first terminal of current mirror 312 and draws a mirrored/amplified current into the second and third terminals of current mirror 312. Because the second terminal of current mirror is coupled to the output of diode 204 and the third terminal of current mirror is coupled to the output of diode 214 (e.g., via the current path of transistor 216), current is pulled out of the diodes 204, 214 to compensate for the excess current initially provided by diodes 204, 214 until the leakage current settles.

The amount of current pulled into the second and third terminals of current mirror 312 is the same as the amount of excess current output by diodes 204, 214 over the steady state diode output current (e.g., after the leakage current has settled). For example, if diode 308 is the same as diodes 204, 214, then the current output by diode 308 is the same as the current output by diodes 204, 214 and no amplification is needed. However, if diode 308 is a scaled down version of diodes 204, 214, then current source 310 will generate a different steady state current based on the scaled down properties of diode 308 and the current into the first terminal of current mirror 312 will be scaled down. In such an example, current mirror 312 can amplify the current at the first terminal as a function of the scale of diode 308 to ensure that the current being pumped away from diodes 204, 214 is sufficient to cause the diode current from transistors 202, 216 to be steady after a transition.

During a transition from diode 308 conducting to not conducting (e.g., when the switches 302, 304 and transistors 202, 218 open and the switch 306 and transistors 224, 234 close). The leaky substrate terminal of diode 308 (e.g., like the substrate terminals of diodes 204, 214) provides a path to ground for a duration of time corresponding to the time constant, thereby causing current to be drawn from supply voltage terminal (Vdd) through the first terminal of the current mirror 314, into the anode of diode 308 and to ground via the leaky substrate terminal of diode 308. The current flowing out of the first terminal of current mirror 314 is mirrored and/or amplified and pumped into nodes of driver 110 (e.g., the anode of diode 204 and the cathode of diode 214), thereby compensating for the negative current generated by the leaky substrate of diodes 204, 214. As the leaky substrate terminal of diode 308 settles and stops leaking current to ground, the current out of the first terminal of current mirror 314 becomes zero, thus no current is pumped into the nodes of driver 110. Accordingly, the current output by diodes 204, 214 remains level after a transition, thereby reducing common mode mismatch and emissions.

In the example of FIG. 3, current mirror 312 is implemented by n-channel metal-oxide semiconductor field-effect transistors (MOSFETs), each with a gate terminal, a first drain terminal, and a second source terminal. Alternatively, current mirror 312 may be implemented by n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 3, the current mirror 314 is implemented by p-channel MOSFETs, each with a gate terminal, a first source terminal, and a second drain terminal. Alternatively, current mirror 314 may be implemented by p-channel FETs, p-channel IGBTs, p-channel JFETs, PNP BJTs, or, with slight modifications, N-type equivalent devices. The gate terminal is an example of a control terminal and the source and drain terminals are examples of current path terminals. Additionally, a current path of a transistor corresponds to the path between the source and drain of a transistor.

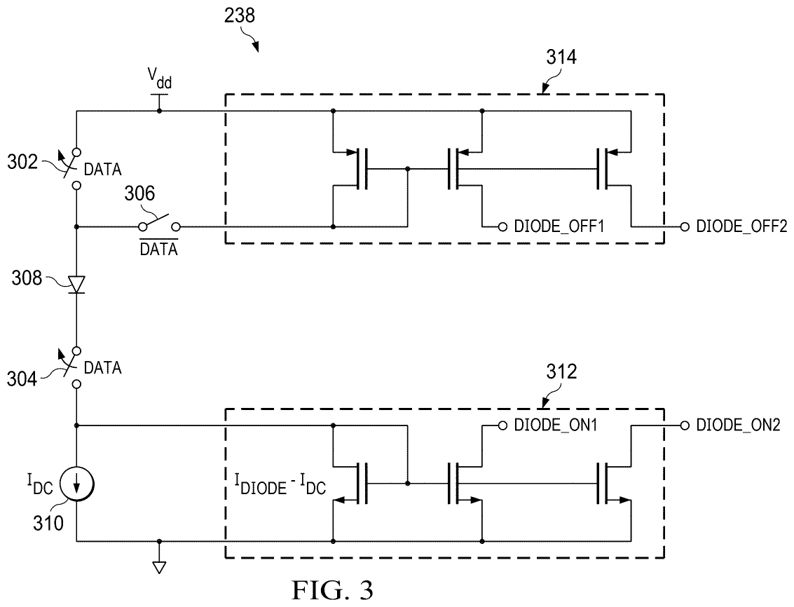

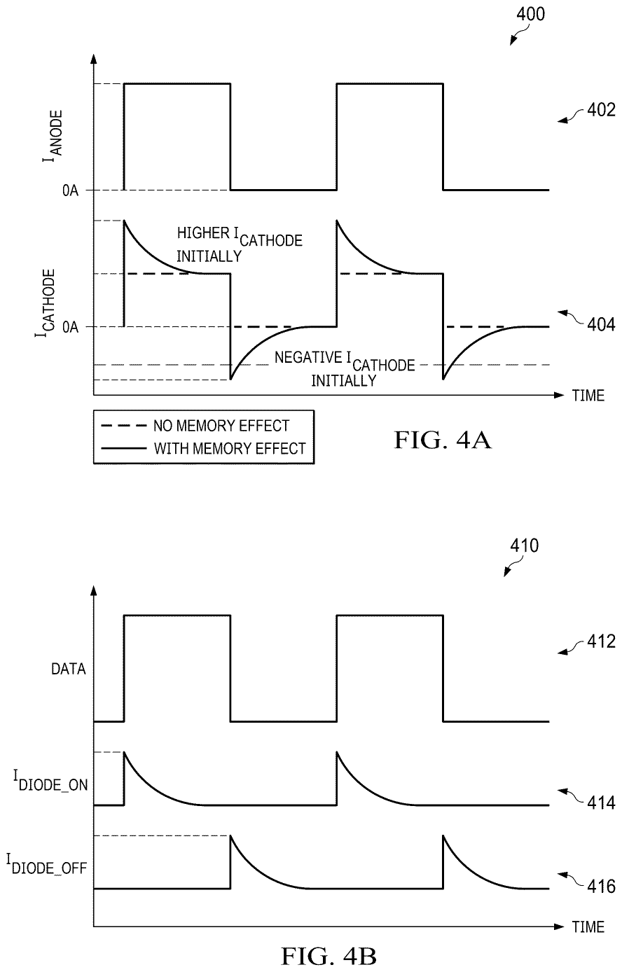

FIG. 4A is a timing diagram 400 illustrating input diode current 402 into the anode of a diode and output diode current 404 out from the cathode of the diode in a system that does not utilize leakage current compensation circuit 238, 240 of FIGS. 2 and/or 3.

As shown in timing diagram 400, the input diode current 402 transitions back and forth from high to zero based on the data or data bar signal. When input diode current 402 transitions high, the output diode current 404 also transitions high. However, after the transition and without leakage compensation, the leakage current through the substrate terminal increase which causes the output diode current 404 to decrease until the leakage current settles to a steady state current. Additionally, when input diode current 402 transitions low and without leakage compensation, the differential bus pulls current from the leaky substrate terminal of diode 204 causing output current 404 to go negative for a duration of time until settling.

FIG. 4B is a timing diagram 400 illustrating data signal 412 applied to switches 302, 304 and transistors 202, 218 of FIGS. 2 and/or 3, I_{DIODE_ON} current 414 pulled away from diode 204 during low to high data transmission, and I_{DIODE_OFF} current 416 pumped into diode 204 for high to low data transitions. However, FIG. 4A can be described in conjunction with any diode 204, 214, 226, 230. I_{DIODE_ON} current 414 is the current pulled into the second terminal of current mirror 312 (e.g., I_{DIODE_ON1} in FIGS. 2 and 3) and I_{DIODE_OFF} current 416 is the current pumped into the second terminal of current mirror 314 (e.g., I_{DIODE_OFF1} in FIGS. 2 and 3).

As data signal 412 transitions high, I_{DIODE_ON} current 414 pulses before settling. As data signal 412 transitions low, I_{DIODE_OFF} current 416 pulses before settling. Because I_{DIODE_ON} current 414 is pulled from the output of diode 204, I_{DIODE_ON} current 414 compensates for the memory effect associated with the leakage current with the time constant. For example, the I_{DIODE_ON} current 414 is subtracted from the output diode current 404 to create a level output diode current with no memory effect. Additionally, because I_{DIODE_OFF} current 416 is pumped into the output of diode 204, I_{DIODE_OFF} current 416 compensates for the memory effect associated with the current pulled from the leaky substrate terminal of diode 204 with the time constant. For example, the I_{DIODE_OFF} current 416 is subtracted from the output diode current 404 to create a level output diode current with no memory effect.

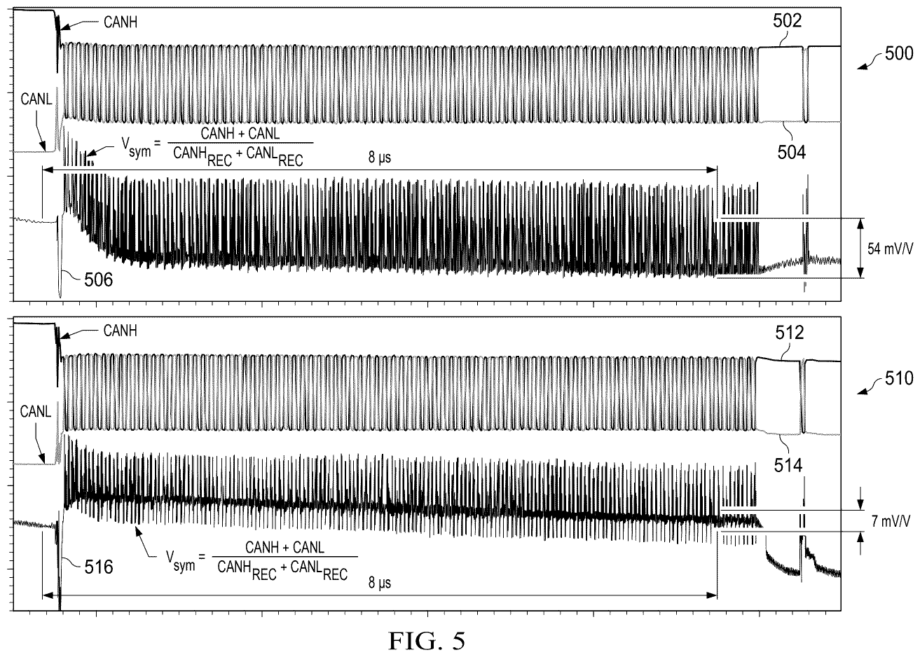

FIG. 5 is a comparison of common mode mismatch between a driver with no leakage current compensation to driver 110 with leakage current compensation circuit 238, 240 of FIGS. 2-3, according to an embodiment of the present disclosure. FIG. 5 includes first timing diagram 500 for a driver with no leakage current compensation and second timing diagram 510 for driver 110 with leakage current compensation circuits 238, 240. First timing diagram 500 includes CANH signal 502, CANL signal 504 and common mode mismatch (also referred to a symmetry voltage) signal 506. Second timing diagram 510 includes CANH signal 512, CANL signal 514 and common mode mismatch (also referred to a symmetry voltage) signal 516. As shown in first timing diagram 500 after 8 microseconds the common mode mismatch is 54 millivolts (mV) per V. However, second timing diagram 510 has a common mode mismatch of 7 mV/V, which is a significant improvement in drift from steady state common mode voltage.

FIG. 6 is a circuit implementation of VOD comparator circuit 114 of FIG. 1, according to an embodiment of the present disclosure. VOD comparator circuit 114 includes OOB comparator circuit 600, SIC comparator circuit 602, logic AND gate 604, delay circuit 606, and multiplexer (MUX) 608. Other implementations are also possible.

In operation, OOB comparator circuit 600 receives the voltage on the CANH connection and the CANL connection and determines the differential voltage (e.g., VOD=CANH−CANL). If the VOD is above a maximum data/fast mode threshold (e.g., −250 mV), OOB comparator circuit 600 outputs a logic high voltage, OOB comparator circuit 600 continues to output the logic high voltage until the VOD drops below a minimum data/fast mode threshold (e.g., −450 mV). After the VOD drops below the minimum data/fast mode threshold, the OOB comparator circuit 600 changes the output to a logic low voltage until the VOD rises above the maximum data/fast mode threshold. The output of OOB comparator circuit 600 is applied to the second input of MUX 608.

SIC comparator circuit 602 receives the voltage on the CANH connection and the CANL connection and determines the differential voltage (e.g., VOD=CANH−CANL). If the VOD is above a maximum SIC mode threshold (e.g., 900 mV), SIC comparator circuit 602 outputs a logic low voltage, SIC comparator circuit 602 continues to output the logic high voltage until the VOD drops below a minimum SIC mode threshold (e.g., 450 mV). After the VOD drops below the minimum SIC mode threshold, the SIC comparator circuit 602 changes the output to a logic high voltage until the VOD rises above the maximum SIC mode threshold. The output of SIC comparator circuit 602 is applied to input of delay circuit 606 and the second input of AND gate 604.

Responsive to VOD being higher than the maximum SIC threshold (e.g., 900 mV) (e.g., based on a falling edge of the output of SIC comparator circuit 602), delay circuit 606 outputs a high voltage pulse for a duration of time (e.g., 1 microsecond) as a select signal or select voltage to the select terminal of MUX 608. When the MUX 608 obtains the high voltage pulse of delay circuit 606, MUX 608 outputs VDD and masks the output of OOB comparator circuit 600. Thus, when VOD is greater than the maximum SIC threshold, the output of OOB comparator circuit 600 is masked for the duration of time (e.g., 1 microsecond). By masking the output of the OOB comparator circuit 600, VOD comparator circuit 114 avoids glitches that trigger OOB comparator circuit 600 triggers when ringing, which causes the VOD to drop below the minimum data/fast threshold, as further described above. When the output of delay circuit 606 is a low voltage, MUX 608 outputs the output signal from OOB comparator circuit 600. The output of MUX 608 is applied to the first terminal of logic AND gate 604 and the output of the SIC comparator circuit 602 is applied to the second terminal of the logic AND gate 604.

Logic AND gate 604 performs a logic AND function to the signal output from MUX 608 and the signal output from SIC comparator circuit 602. The output of the logic AND gate is the RXD signal applied to controller 102 of FIG. 1 to indicate whether the CANH and CANL connections are idle or busy. During SIC mode, the VOD is typically between a high voltage and a zero voltage. When VOD is between a high voltage and a zero voltage, OOB comparator circuit 600 outputs a logic high. Thus, the output of the logic AND gate 604 corresponds to the output of SIC comparator circuit 602. If CANH and CANL connections have ringing during SIC mode, the VOD may unintentionally decrease below the minimum data/fast threshold, thereby causing OOB comparator circuit 600 to output a logic zero, which may result in a glitch. However, during this duration of time the OOB comparator circuit 600 is masked due to the VOD being greater than the SIC-RX threshold in SIC mode, which triggers the masking of the OOB comparator circuit 600 for a duration of time long enough to mask the glitch. During data/fast mode, the VOD is typically between a low positive voltage (e.g., 1 V and a low negative voltage (e.g., −1). When VOD is between a low positive voltage and a low negative voltage, SIC comparator circuit 602 outputs a logic high. Thus, the output of the logic AND gate 604 corresponds to the output of the OOB comparator circuit 600.

As described above, the RXD output of logic AND gate 604 is provided to controller 102 of FIG. 1 so that controller 102 can determine whether the differential interface/connection/bus is busy or idle. When VOD is greater than the maximum SIC threshold, RXD goes to a logic low voltage, reflecting a dominant bit to controller 102. Responsive to obtaining the dominant bit, controller 102 determines that the differential interface/connection/bus is busy and will not initiate transmission of data for at least 2 microseconds (e.g., due to inter-frame space that occurs after a dominant bit between an ACK and a start of frame for the CAN protocol). Thus, the output of OOB comparator circuit 600 does not provide any useful information since controller 102 will not initiate communication for at least another 2 microseconds. However, as explained above, ringing on the differential interface/connection/bus can cause overshoot and undershoot of VOD, which can lead to a VOD below the minimum data threshold, which causes a glitch. Thus, MUX 608 masks the output of OOB comparator circuit 600 for a duration of time (e.g., 1 microsecond) where the glitch may occur because the OOB comparator circuit 600 does not provide any useful information for at least 2 microseconds after VOD is greater than the maximum SIC threshold.

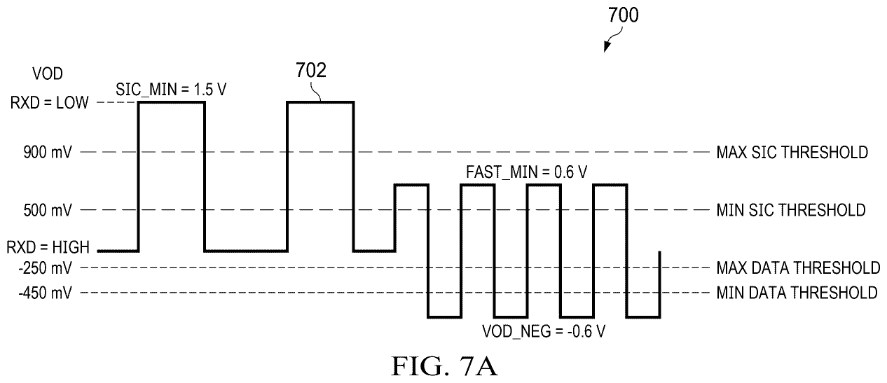

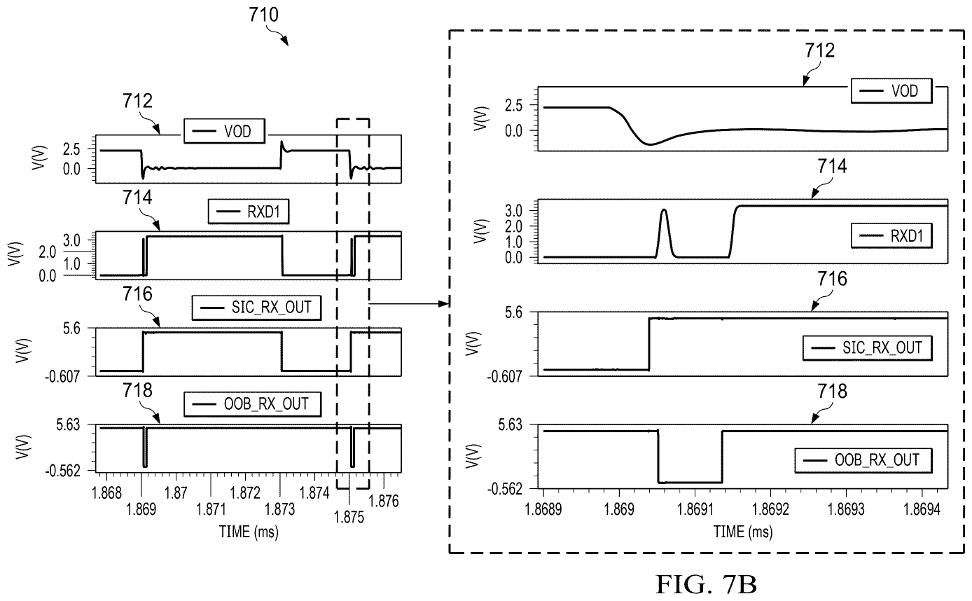

FIG. 7A is a diagram 700 illustrating VOD signal 702 (e.g., CANH-CANL) in both SIC/slow and data/fast mode. The VOD signal 702 initially corresponds to SIC/slow mode, where VOD signal 702 adjusts between zero voltage and a minimum of 1.5 V. After SIC/slow mode, VOD signal 702 changes to data/fast mode, where VOD signal 702 adjusts between 0.6 V and −0.6 V. In the example of FIG. 7A, the maximum SIC threshold is 900 mV for SIC comparator circuit 602 of FIG. 6, the minimum SIC threshold is 500 mV for SIC comparator circuit 602 of FIG. 6, the maximum data threshold is −250 mV for OOB comparator circuit 600 of FIG. 6, and the minimum data threshold id −450 m V for OOB comparator circuit 600 of FIG. 6.

FIG. 7B is a diagram 710 illustrating the glitch that can occur when OOB comparator circuit output is not masked and there is ringing on the differential bus connection. Diagram 710 includes VOD signal 712, RXD signal 714, SIC comparator output signal 716, and OOB comparator output signal 718.

FIG. 7B illustrates SIC mode communication on the CANH and CANL connections. Accordingly, VOD signal 712 transitions back and forth between 2.5 V and 0 V. However, due to noise and/or ringing on the CANH and CANL connections, when VOD signal 712 transition from a low voltage to a high voltage, VOD signal 712 overshoots the high voltage. Likewise, when VOD signal 712 transitions from the high voltage to the low voltage, VOD signal 712 undershoots the low voltage. When VOD signal 712 drops below the minimum SIC threshold, SIC comparator output signal 716 adjusts from a logic low voltage to a logic high voltage, thereby causing RXD signal 714 to also adjust from a logic low to a logic high because both SIC comparator output signal 716 and OOB comparator output signal 718 are logic high (e.g., AND (1, 1)=1). However, the ringing causes the VOD signal 712 to drop below the minimum data/fast threshold of OOB comparator circuit 600, thereby causing the OOB comparator signal 718 to drop to a logic low for a duration of time until the VOD signal 712 rises back up above the maximum data/fast threshold of the OOB comparator circuit 600. The OOB comparator signal 718 dropping low for a duration of time causes RXD signal 714 to also drop low for the duration of time, which reflects the glitch.

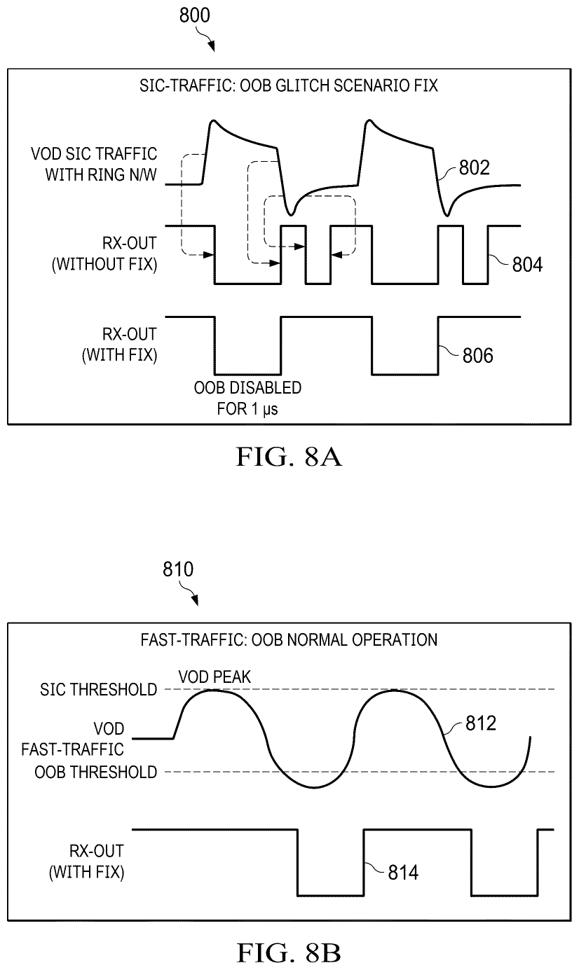

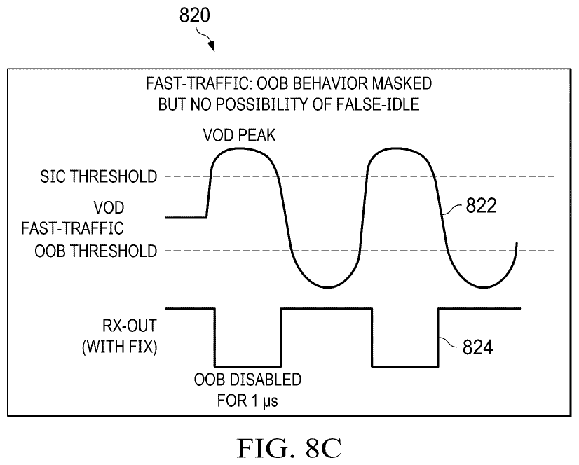

FIGS. 8A-8C illustrates three timing diagrams 800, 810, 820 illustrating VOD comparator circuit 114 outputs for different differential interface scenarios. Timing diagram 800 of FIG. 8A includes VOD signal 802, RXD output signal 804 without OOB masking, and RXD output signal 806 with OOB masking. Timing diagram 810 of FIG. 8B includes VOD signal 812 and RXD output signal 814. Timing diagram 820 of FIG. 8C includes VOD signal 822 and RXD output signal 824. VOD signals 802, 812, 822 correspond to a differential voltage between received voltages of the CANH and CANL connections of FIGS. 1 and/or 6. RXD signals 806, 814, 816 correspond to the RXD output of VOD comparator circuit 114 of FIGS. 1 and/or 6. RXD output 804 corresponds to an RXD output without OOB masking. Other implementations are also possible.

VOD signal 802 of FIG. 8A corresponds to SIC/slow mode with ringing that causes overshoot and undershoot. Typically, when VOD signal 802 is low (e.g., 0 V), RX signal 804 is high and when VOD signal 802 is high (e.g., 2.5 V), RX signal 804 is low. However, as described above, the ringing causes undershooting when VOD signal 802 decreases from a high voltage to a low voltage. The undershooting creates a VOD voltage low enough to trigger OOB comparator to generate a logic low voltage which creates the glitch on the RXD signal 804. However, because VOD comparator circuit 114 masks the OOB comparison output for a duration of time after VOD is greater than the maximum SIC threshold, RXD signal 806 does not include the glitch of RXD signal 804.

VOD signal 812 of FIG. 8B corresponds to data/fast mode with limited or no ringing. In data/fast mode, when VOD signal 802 toggles between a positive voltage (0.6 V) lower than the maximum SIC threshold (e.g., 0.9 V) and a negative voltage (e.g., −0.6 V) lower than the minimum data/fast threshold (e.g., −0.45 V). Because VOD signal 812 is lower than the maximum SIC threshold, OOB comparator output is not masked and the RXD signal 814 is controlled by the OOB comparison. Thus, after VOD signal 812 decreases below the minimum data/fast threshold, RXD signal 814 goes to a logic low and after VOD signal 812 increases above the maximum data/fast threshold, RXD signal 814 goes to a logic high.

VOD signal 822 of FIG. 8C corresponds to data/fast mode with ringing that causes overshoot and undershoot. In data/fast mode, typically, when VOD signal 802 toggles between a positive voltage (0.6 V) lower than the maximum SIC threshold (e.g., 0.9 V) and a negative voltage (e.g., −0.6 V) lower than the minimum data/fast threshold (e.g., −0.45 V). However, as described above, the ringing causes overshooting when ROV signal 822 increases from a low voltage to a high voltage. The overshooting creates a VOD voltage higher than the maximum SOC threshold, which causes RXD signal 824 to drop to a logic low voltage indicating to controller 102 that the differential connection is busy and causes the output of OOB comparator circuit 600 to be masked. However, because controller 102 will not initiate communication for at least 2 microseconds after determining the differential connection is busy, masking the output of the OOB comparator circuit 600 does not provide any useful information for the duration of the making because the controller 102 is already aware that the differential connection is busy.

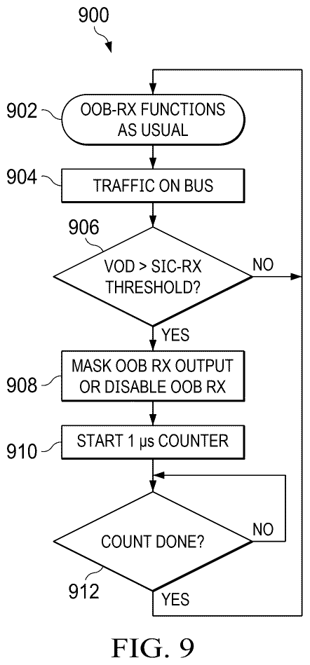

FIG. 9 is a flowchart of embodiment method 900, according to an embodiment of the present disclosure. The steps/blocks of FIG. 9 are described with respect to VOD comparator circuit 114 of FIGS. 1 and/or 6. However, FIG. 9 could be described in conjunction with any receiver that obtains differential voltages.

Method 900 begins at block 902, at which VOD comparator circuit 114 operates by causing both the output of OOB comparator circuit 600 and SIC comparator circuit 602 to be applied to logic AND gate 604 to generate the RXD signal, which is output to controller 102. For example, initially, delay circuit 606 outputs a signal to select terminal of MUX 608 and MUX 608 outputs the output of OOB comparator circuit 600 to the logic AND gate 604. At block 904, logic AND gate 604 generates the RXD signal based on the traffic (e.g., voltages, signals, etc.) on the differential bus. For example, OOB comparator circuit 600 compares the VOD (e.g., CANH-CANL) to a maximum and minimum data/fast threshold to generate a first output, SIC comparator circuit 602 compares the VOD (e.g., CANH-CANL) to a maximum and minimum SIC/slow threshold to generate a second output, and logic AND gate 604 generates the RXD output based on a logic AND function of the first output and the second output.

At block 906, SIC comparator circuit 602 determines if the VOD is greater than the maximum SIC threshold. The VOD may be greater than the maximum SIC threshold during SIC mode or during data mode when there is higher overshoot from ringing. If SIC comparator circuit 602 determines that the VOD is not greater than the maximum SIC threshold (block 906: NO), control returns to block 902 for normal operation without masking the output of the OOB comparator circuit 600. If SIC comparator circuit 602 determines that the VOD is greater than the maximum SIC threshold (block 906: YES), MUX 608 masks and/or disables the output of OOB comparator circuit 600 and outputs a logic high voltage (Vdd) (block 908). For example, when SIC comparator circuit 602 determines that the VOD is greater than the maximum SIC threshold, the output of SIC comparator circuit 602 drops to a logic low voltage, thereby triggering delay circuit 606 to generate a logic high voltage to the select terminal of MUX 608 for a duration of time to cause MUX 608 to mask the output of OOB comparator circuit 600.

At block 910, delay circuit 606 starts a counter for a duration of time (e.g., 1 microsecond) to mask OOB output to avoid a glitch. At block 912, delay circuit 606 determines if the count is complete. If delay circuit 606 determines that the count is not complete (block 912: NO), MUX 608 continues to mask the output of OOB comparator circuit 600 and control returns to block 912 until the count is complete. If delay circuit 606 determines that the count is complete (block 912: YES), delay circuit 606 returns the voltage at the select terminal of MUX 608 to a logic low voltage to stop masking the output of OOB comparator circuit 600 and control returns to block 902.

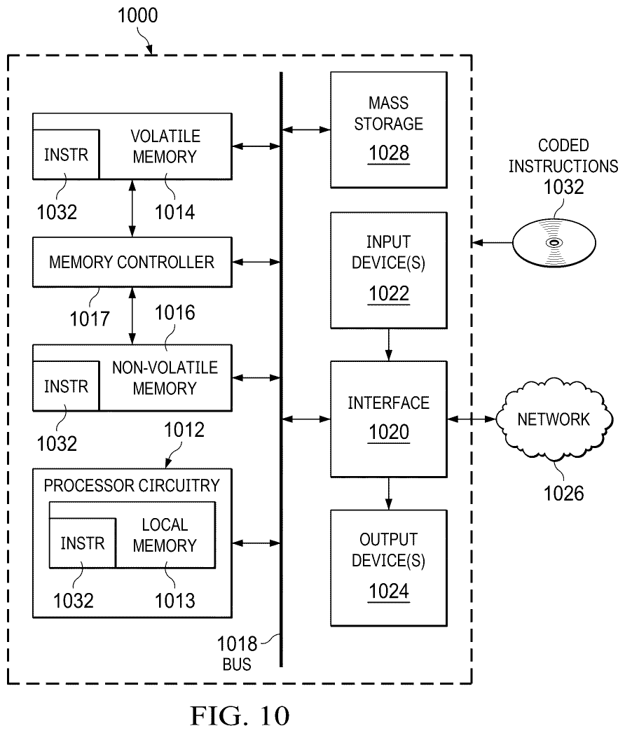

FIG. 10 is a block diagram of an example programmable circuitry platform 1000 structured to one or a combination of execute or instantiate one or more of the example machine-readable instructions or the example operations of FIG. 9 to implement the VOD comparator circuit 114 of FIG. 6. The programmable circuitry platform 1000 can be, for example, a server, a personal computer, a workstation, a self-learning machine (e.g., a neural network), a mobile device (e.g., a cell phone, a smart phone, a tablet such as an iPad™M), an Internet appliance, or any other type of computing or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, or microcontrollers from any desired family or manufacturer. The programmable circuitry 1012 may be implemented by one or more semiconductor based (e.g., silicon based) devices. In this example, the programmable circuitry 1012 implements VOD comparator circuit 114 of FIGS. 1 and/or 6.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by bus 1018. The volatile memory 1014 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1016 may be implemented by one or a combination of flash memory or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016.

The programmable circuitry platform 1000 of the illustrated example also includes interface circuitry 1020. The interface circuitry 1020 may be implemented by hardware according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1022 are connected to the interface circuitry 1020. The input device(s) 1022 permit(s) a user (e.g., a human user, a machine user, etc.) to enter one of or a combination of data or commands into the programmable circuitry 1012. The input device(s) 1022 can be implemented by, for example, one of or a combination of an audio sensor, a microphone, a camera (still or video), a keyboard, a button, a mouse, a touchscreen, a trackpad, a trackball, or a voice recognition system.

One or more output devices 1024 are also connected to the interface circuitry 1020 of the illustrated example. The output device(s) 1024 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, or speaker. The interface circuitry 1020 of the illustrated example, thus, includes one of or a combination of a graphics driver card, a graphics driver chip, or graphics processor circuitry such as a GPU.

The interface circuitry 1020 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store one or more of firmware, software, or data. Examples of such mass storage discs or devices 1028 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1032, which may be implemented by the machine-readable instructions of FIG. 9, may be stored in one of or a combination of the mass storage device 1028, in the volatile memory 1014, in the non-volatile memory 1016, or on at least one non-transitory computer readable storage medium such as a CD or DVD which may be removable.

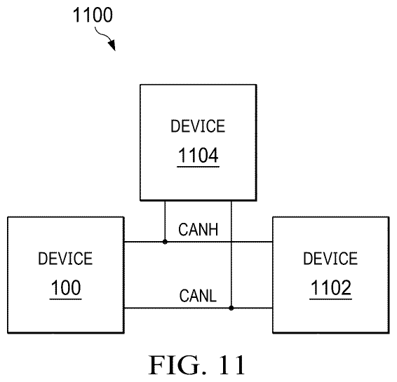

FIG. 11 illustrates system 1100 which implements device 100 of FIG. 1 in communication with devices 1104, 1102. However, system 1100 may include any number of devices. In system 1100, devices 100, 1104, 1102 share a differential interface made up of CANH and CANL connections. Transmitter circuit 106 of device 100 can transmit data to one or more of devices 1102, 1104 using the CANH and CANL connections. Additionally, receiver circuit 112 of device 100 can process the voltage differential between CANH and CANL to identify if the shared interface is idle or busy (e.g., currently being utilized by device 1102 or 1104) using examples disclosed herein. System 1100 may be a vehicular system, where one or more of devices 100, 1104, 1104 may be a central controller, domain specific controllers, sensors etc. However, system 1100 may be implemented in a different system that utilizes differential connections, such as industrial automation systems.

While an example manner of the driver 110 of FIG. 1 is illustrated in FIGS. 2 and 3 and an example manner of implementing VOD comparator circuit 114 is illustrated in FIG. 6, one or more of the elements, processes, and/or devices illustrated in FIGS. 2, 3 and/or 6 may be combined, divided, re-arranged, omitted, eliminated, and/or implemented in any other way. Further, the transistors 200, 202, 206, 216, 218, 220, 222, 224, 228, 232, 234, 236, the diodes 204, 214, 226, 230, resistors 118, 120, capacitor 122, switches 302, 304, 306, diode 308, current source 310, current mirrors 312, 314, comparator circuits 600, 602, logic AND gate 604, delay circuit 606, MUX 608, and/or, more generally, the driver 110, the leakage current compensation circuits 238, 240, and/or the VOD comparator circuit 114, may be implemented by hardware alone or by hardware in combination with software and/or firmware. Thus, for example, any of the transistors 200, 202, 206, 216, 218, 220, 222, 224, 228, 232, 234, 236, the diodes 204, 214, 226, 230, resistors 118, 120, capacitor 122, switches 302, 304, 306, diode 308, current source 310, current mirrors 312, 314, comparator circuits 600, 602, logic AND gate 604, delay circuit 606, MUX 608, and/or, more generally, the driver 110, the leakage current compensation circuits 238, 240, and/or the VOD comparator circuit 114, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the driver 110, the leakage current compensation circuits 238, 240, and/or the VOD comparator circuit 114 of FIGS. 2, 3, and/or 6 may include one or more elements, processes, and/or devices in addition to, or instead of, those illustrated in FIGS. 2, 3, and/or 6, and/or may include more than one of any or all of the illustrated elements, processes and devices.

Flowchart(s) representative of example machine readable instructions, which may be executed by programmable circuitry to implement and/or instantiate the VOD comparator circuit 114 of FIG. 6 and/or representative of example operations which may be performed by programmable circuitry to implement and/or instantiate the VOD comparator circuit 114 of FIG. 6, are shown in FIG. 9. The machine-readable instructions may be one or more executable programs or portion(s) of one or more executable programs for execution by programmable circuitry. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. Similarly, the non-transitory computer readable storage medium may include one or more mediums.

Although the example program is described with reference to the flowchart(s) illustrated in FIG. 9, many other methods of implementing the VOD comparator circuit 114 of FIG. 6 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)).

As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUS, VPUs, and/or one or more FPGAs in a single machine, multiple CPUs, GPUs, VPUs, and/or FPGAs distributed across multiple servers of a server rack, and/or multiple CPUs, GPUS, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

As mentioned above, the example operations of FIG. 9 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine-readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” may be understood to include (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry may be understood as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example embodiments of the present disclosure are summarized here. Other embodiments can also be understood from the entirety of the specification and the claims filed herein.

Example methods, apparatus, systems, and articles of manufacture to methods and apparatus to increase performance of a transceiver are disclosed herein. Further examples and combinations thereof include the following:

Example 1 includes a circuit comprising a transistor having a first terminal, a first diode having an input terminal and an output terminal, the input terminal of the first diode coupled to the first terminal of the transistor, the first diode configured to, when conducting, pass a first diode current from the input terminal of the first diode to the output terminal of the first diode, the first diode current includes a first leakage current of the first diode, a second diode having an input terminal and an output terminal, the second diode configured to, when conducting, pass a second diode current from the input terminal of the second diode to the output terminal of the second diode, the second diode current includes a second leakage current of the second diode, the second diode current corresponding to the first diode current, a current source having an input terminal coupled to the output terminal of the second diode, the current source configured to generate a steady state current corresponding to the first diode current at steady state, and a current mirror having a first terminal and a second terminal, the first terminal of the current mirror coupled to the output terminal of the second diode and the input terminal of the current source, the second terminal of the current mirror coupled to the input terminal of the first diode, the current mirror configured to compensate for the first leakage current based on the second leakage current.

Example 2 includes the circuit of any preceding clause, wherein the current mirror is a first current mirror, further including a second current mirror having a first terminal and a second terminal, the first terminal of the second current mirror coupled to the input terminal of the second diode, the second terminal of the current mirror coupled to the input terminal of the first diode, the second current mirror configured to compensate for the first leakage current based on the second leakage current.

Example 3 includes the circuit of any preceding clause, wherein the first current mirror is configured to compensate for the first leakage current of the first diode when the first diode conducts and the second current mirror is configured to compensate for the first leakage current of the second diode when the first diode is not conducting.

Example 4 includes the circuit of any preceding clause, further including a first switch having a current path, the input terminal of the second diode coupled to a supply terminal through the current path of the first switch, a second switch having a current path, the output terminal of the second diode coupled to the input terminal of the current source through the current path of the second switch, the second switch configured to close the first switch closes, and a third switch having a current path, the input terminal of the second diode coupled to the first terminal of the second current mirror through the current path of the third switch, the second switch configured to close the first switch closes.

Example 5 includes the circuit of any preceding clause, wherein the transistor has a control terminal, the first switch has a control terminal coupled to the control terminal of the transistor, and the second switch has a control terminal coupled to the control terminals of the transistor and the first switch.

Example 6 includes the circuit of any preceding clause, wherein the first leakage current and the second leakage current corresponds to a time constant.

Example 7 includes the circuit of any preceding clause, wherein the current mirror is configured to mirror a differential current at the first terminal of the current mirror to the second terminal of the current mirror, the differential current corresponding to a difference between the second diode current and the steady state current.

Example 8 includes the circuit of any preceding clause, wherein the transistor, the first diode the second diode, the current source and the current mirror is included in a transmitter circuit, further including a receiver circuit, the receiver circuit including a first comparator circuit configured to generate a first output based on a comparison of a differential voltage on a differential connection to a first threshold, a second comparator circuit configured to generate a second output based on a comparison of the differential voltage on the differential connection to a second threshold different than the first threshold, a delay circuit coupled to the second comparator circuit, the delay circuit configured to output a first select voltage for a duration of time when the differential voltage is greater than the second threshold, and a multiplexer having a first input terminal, a second input terminal, and a select terminal, the first input terminal of the multiplexer coupled to a supply voltage terminal, the second input terminal of the multiplexer coupled to the first comparator circuit, and the select terminal of the multiplier coupled to the delay circuit, the multiplexer configured to output a supply voltage from the supply voltage terminal when the delay circuit outputs the first select voltage and output the first output of the first comparator circuit when the delay circuit outputs a second select voltage different than the first select voltage.

Example 9 includes a circuit comprising a first comparator circuit having an output terminal, the first comparator circuit configured to generate a first output voltage based on a differential voltage on a differential connection, the first output voltage being a first voltage based on the differential voltage being greater than a first threshold, the first output voltage being a second voltage based on the differential voltage being less than a second threshold, a second comparator circuit having an output terminal, the second comparator circuit configured to generate a second output voltage based on the differential voltage, the second output voltage being a third voltage based on the differential voltage being greater than a third threshold different than the first and second thresholds, a delay circuit having an input terminal and an output terminal, the input terminal of the delay circuit coupled to the output terminal of the second comparator circuit, coupled to the second comparator circuit, the delay circuit configured to pulse a select signal to a high voltage for a duration of time based on the second output voltage becoming the third voltage, and a multiplexer having a first input terminal, a second input terminal, and a select terminal, the first input terminal of the multiplexer coupled to a supply voltage terminal, the second input terminal of the multiplexer coupled to the output terminal of the first comparator circuit, and the select terminal of the multiplier coupled to the output terminal of the delay circuit, the multiplexer configured to mask the first output voltage of the first comparator circuit based on the select signal being the high voltage, and output the first output voltage of the first comparator circuit based on the select signal being a low voltage.

Example 10 includes the circuit of any preceding clause, further including a logic AND gate having a first input terminal, a second input terminal, and an output terminal, the first input terminal of the logic AND gate coupled to an output terminal of the multiplexer, the second input terminal of the logic AND gate coupled to the output terminal of second comparator.

Example 11 includes the circuit of any preceding clause, wherein the output terminal of the logic AND gate is coupled to a controller.

Example 12 includes the circuit of any preceding clause, wherein the first comparator circuit has a first input terminal and a second input terminal, the first input terminal of the first comparator circuit coupled to a high connection of the differential connection, the second input terminal of the first comparator circuit coupled to a low connection of the differential connection, and the second comparator circuit has a first input terminal and a second input terminal, the first input terminal of the second comparator circuit coupled to the high connection of the differential connection, the second input terminal of the second comparator circuit coupled to the low connection of the differential connection.

Example 13 includes the circuit of any preceding clause, wherein the first comparator circuit, the second comparator circuit, the delay circuit, and the multiplexer are included in a receiver circuit, further including a transmitter circuit, the transmitter circuit including a transistor having a first terminal, a first diode having an input terminal and an output terminal, the input terminal of the first diode coupled to the first terminal of the transistor, the first diode configured to, when conducting, pass a first diode current from the input terminal of the first diode to the output terminal of the first diode, the first diode current includes a first leakage current of the first diode, a second diode having an input terminal and an output terminal, the second diode configured to, when conducting, pass a second diode current from the input terminal of the second diode to the output terminal of the second diode, the second diode current includes a second leakage current of the second diode, the second diode current corresponding to the first diode current, a current source having an input terminal coupled to the output terminal of the second diode, the current source configured to generate a steady state current corresponding to the first diode current at steady state, and a current mirror having a first terminal and a second terminal, the first terminal of the current mirror coupled to the output terminal of the second diode and the input terminal of the current source, the second terminal of the current mirror coupled to the input terminal of the first diode, the current mirror configured to compensate for the first leakage current based on the second leakage current.

Example 14 includes a method comprising passing a first diode current from an input terminal of a first diode to an output terminal of the first diode, the first diode current includes a first leakage current of the first diode, passing a second diode current from an input terminal of the second diode to an output terminal of the second diode, the second diode current includes a second leakage current of the second diode, the second diode current corresponding to the first diode current, generating a steady state current corresponding to the first diode current at steady state, and compensating for the first leakage current based on a difference between the second leakage current and the steady state current.

Example 15 includes the method of any preceding clause, wherein compensating for the first leakage current includes pumping a current into the input terminal of the first diode, the current corresponding to the difference between the second leakage current and the steady state current.

Example 16 includes the method of any preceding clause, wherein the pumping of the current into the input terminal of the first diode includes opening a first switch and a second switch and closing a third switch.

Example 17 includes the method of any preceding clause, wherein compensating for the first leakage current includes pulling a current out from the input terminal of the first diode, the current corresponding to the difference between the second leakage current and the steady state current.

Example 18 includes the method of any preceding clause, wherein the pulling of the current from the input terminal of the first diode includes closing a first switch and a second switch and opening a third switch.

Example 19 includes the method of any preceding clause, wherein the first leakage current and the second leakage current corresponds to a time constant.

Example 20 includes the method of any preceding clause, further including generating a first output based on a comparison of a differential voltage on a differential connection to a first threshold, generating a second output based on a comparison of the differential voltage on the differential connection to a second threshold different than the first threshold, outputting a first select voltage for a duration of time when the differential voltage is greater than the second threshold, and outputting a supply voltage or the first output based on the first select voltage.

Example 21 includes a method comprising generating a first output voltage based on a differential voltage on a differential connection, the first output voltage being a first voltage based on the differential voltage being greater than a first threshold, the first output voltage being a second voltage based on the differential voltage being less than a second threshold, generating a second output voltage based on the differential voltage, the second output voltage being a third voltage based on the differential voltage being greater than a third threshold different than the first and second thresholds, pulsing a select signal to a high voltage for a duration of time based on the second output voltage becoming the third voltage, masking the first output voltage based on the select signal being the high voltage, and outputting the first output voltage based on the select signal being a low voltage.

Example 22 includes the method of any preceding clause, further including determining whether the differential voltage is associated with a data operation mode or a signal improvement capability (SIC) mode.

Example 23 includes the method of any preceding clause, wherein the first threshold and the second threshold are based on the determination that the differential voltage is associated with the data operation mode or the SIC mode.

Example 24 includes the method of any preceding clause, further including masking the first output voltage for a predetermined amount of time based on the select signal being the high voltage.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. A circuit comprising:
a transistor having a first terminal;
a first diode having an input terminal and an output terminal, the input terminal of the first diode coupled to the first terminal of the transistor, the first diode configured to, when conducting, pass a first diode current from the input terminal of the first diode to the output terminal of the first diode, the first diode current includes a first leakage current of the first diode;
a second diode having an input terminal and an output terminal, the second diode configured to, when conducting, pass a second diode current from the input terminal of the second diode to the output terminal of the second diode, the second diode current includes a second leakage current of the second diode, the second diode current corresponding to the first diode current;
a current source having an input terminal coupled to the output terminal of the second diode, the current source configured to generate a steady state current corresponding to the first diode current at steady state; and
a current mirror having a first terminal and a second terminal, the first terminal of the current mirror coupled to the output terminal of the second diode and the input terminal of the current source, the second terminal of the current mirror coupled to the input terminal of the first diode, the current mirror configured to compensate for the first leakage current based on the second leakage current.

2. The circuit of claim 1, wherein the current mirror is a first current mirror, further including a second current mirror having a first terminal and a second terminal, the first terminal of the second current mirror coupled to the input terminal of the second diode, the second terminal of the current mirror coupled to the input terminal of the first diode, the second current mirror configured to compensate for the first leakage current based on the second leakage current.

3. The circuit of claim 2, wherein the first current mirror is configured to compensate for the first leakage current of the first diode when the first diode conducts and the second current mirror is configured to compensate for the first leakage current of the second diode when the first diode is not conducting.

4. The circuit of claim 2, further including:
a first switch having a current path, the input terminal of the second diode coupled to a supply terminal through the current path of the first switch;
a second switch having a current path, the output terminal of the second diode coupled to the input terminal of the current source through the current path of the second switch, the second switch configured to close the first switch closes; and
a third switch having a current path, the input terminal of the second diode coupled to the first terminal of the second current mirror through the current path of the third switch, the second switch configured to close the first switch closes.

5. The circuit of claim 4, wherein the transistor has a control terminal, the first switch has a control terminal coupled to the control terminal of the transistor, and the second switch has a control terminal coupled to the control terminals of the transistor and the first switch.

6. The circuit of claim 1, wherein the first leakage current and the second leakage current corresponds to a time constant.

7. The circuit of claim 1, wherein the current mirror is configured to mirror a differential current at the first terminal of the current mirror to the second terminal of the current mirror, the differential current corresponding to a difference between the second diode current and the steady state current.

8. The circuit of claim 1, wherein the transistor, the first diode the second diode, the current source and the current mirror is included in a transmitter circuit, further including a receiver circuit, the receiver circuit including:
a first comparator circuit configured to generate a first output based on a comparison of a differential voltage on a differential connection to a first threshold;
a second comparator circuit configured to generate a second output based on a comparison of the differential voltage on the differential connection to a second threshold different than the first threshold;
a delay circuit coupled to the second comparator circuit, the delay circuit configured to output a first select voltage for a duration of time when the differential voltage is greater than the second threshold; and
a multiplexer having a first input terminal, a second input terminal, and a select terminal, the first input terminal of the multiplexer coupled to a supply voltage terminal, the second input terminal of the multiplexer coupled to the first comparator circuit, and the select terminal of the multiplier coupled to the delay circuit, the multiplexer configured to output a supply voltage from the supply voltage terminal when the delay circuit outputs the first select voltage and output the first output of the first comparator circuit when the delay circuit outputs a second select voltage different than the first select voltage.

9. A circuit comprising:
a first comparator circuit having an output terminal, the first comparator circuit configured to generate a first output voltage based on a differential voltage on a differential connection, the first output voltage being a first voltage based on the differential voltage being greater than a first threshold, the first output voltage being a second voltage based on the differential voltage being less than a second threshold;
a second comparator circuit having an output terminal, the second comparator circuit configured to generate a second output voltage based on the differential voltage, the second output voltage being a third voltage based on the differential voltage being greater than a third threshold different than the first and second thresholds;
a delay circuit having an input terminal and an output terminal, the input terminal of the delay circuit coupled to the output terminal of the second comparator circuit, coupled to the second comparator circuit, the delay circuit configured to pulse a select signal to a high voltage for a duration of time based on the second output voltage becoming the third voltage; and
a multiplexer having a first input terminal, a second input terminal, and a select terminal, the first input terminal of the multiplexer coupled to a supply voltage terminal, the second input terminal of the multiplexer coupled to the output terminal of the first comparator circuit, and the select terminal of the multiplier coupled to the output terminal of the delay circuit, the multiplexer configured to:
mask the first output voltage of the first comparator circuit based on the select signal being the high voltage; and
output the first output voltage of the first comparator circuit based on the select signal being a low voltage.

10. The circuit of claim 9, further including a logic AND gate having a first input terminal, a second input terminal, and an output terminal, the first input terminal of the logic AND gate coupled to an output terminal of the multiplexer, the second input terminal of the logic AND gate coupled to the output terminal of second comparator.

11. The circuit of claim 10, wherein the output terminal of the logic AND gate is coupled to a controller.

12. The circuit of claim 9, wherein:
the first comparator circuit has a first input terminal and a second input terminal, the first input terminal of the first comparator circuit coupled to a high connection of the differential connection, the second input terminal of the first comparator circuit coupled to a low connection of the differential connection; and
the second comparator circuit has a first input terminal and a second input terminal, the first input terminal of the second comparator circuit coupled to the high connection of the differential connection, the second input terminal of the second comparator circuit coupled to the low connection of the differential connection.

13. The circuit of claim 9, wherein the first comparator circuit, the second comparator circuit, the delay circuit, and the multiplexer are included in a receiver circuit, further including a transmitter circuit, the transmitter circuit including:
a transistor having a first terminal;
a first diode having an input terminal and an output terminal, the input terminal of the first diode coupled to the first terminal of the transistor, the first diode configured to, when conducting, pass a first diode current from the input terminal of the first diode to the output terminal of the first diode, the first diode current includes a first leakage current of the first diode;
a second diode having an input terminal and an output terminal, the second diode configured to, when conducting, pass a second diode current from the input terminal of the second diode to the output terminal of the second diode, the second diode current includes a second leakage current of the second diode, the second diode current corresponding to the first diode current;
a current source having an input terminal coupled to the output terminal of the second diode, the current source configured to generate a steady state current corresponding to the first diode current at steady state; and
a current mirror having a first terminal and a second terminal, the first terminal of the current mirror coupled to the output terminal of the second diode and the input terminal of the current source, the second terminal of the current mirror coupled to the input terminal of the first diode, the current mirror configured to compensate for the first leakage current based on the second leakage current.

14. A method comprising:
passing a first diode current from an input terminal of a first diode to an output terminal of the first diode, the first diode current includes a first leakage current of the first diode;
passing a second diode current from an input terminal of the second diode to an output terminal of the second diode, the second diode current includes a second leakage current of the second diode, the second diode current corresponding to the first diode current;
generating a steady state current corresponding to the first diode current at steady state; and
compensating for the first leakage current based on a difference between the second leakage current and the steady state current.

15. The method of claim 14, wherein compensating for the first leakage current includes pumping a current into the input terminal of the first diode, the current corresponding to the difference between the second leakage current and the steady state current.

16. The method of claim 15, wherein the pumping of the current into the input terminal of the first diode includes opening a first switch and a second switch and closing a third switch.

17. The method of claim 14, wherein compensating for the first leakage current includes pulling a current out from the input terminal of the first diode, the current corresponding to the difference between the second leakage current and the steady state current.

18. The method of claim 17, wherein the pulling of the current from the input terminal of the first diode includes closing a first switch and a second switch and opening a third switch.

19. The method of claim 14, wherein the first leakage current and the second leakage current corresponds to a time constant.

20. The method of claim 14, further including:
generating a first output based on a comparison of a differential voltage on a differential connection to a first threshold;
generating a second output based on a comparison of the differential voltage on the differential connection to a second threshold different than the first threshold;
outputting a first select voltage for a duration of time when the differential voltage is greater than the second threshold; and
outputting a supply voltage or the first output based on the first select voltage.

21. A method comprising:
generating a first output voltage based on a differential voltage on a differential connection, the first output voltage being a first voltage based on the differential voltage being greater than a first threshold, the first output voltage being a second voltage based on the differential voltage being less than a second threshold;
generating a second output voltage based on the differential voltage, the second output voltage being a third voltage based on the differential voltage being greater than a third threshold different than the first and second thresholds;
pulsing a select signal to a high voltage for a duration of time based on the second output voltage becoming the third voltage;
masking the first output voltage based on the select signal being the high voltage; and
outputting the first output voltage based on the select signal being a low voltage.

22. The method of claim 21, further including determining whether the differential voltage is associated with a data operation mode or a signal improvement capability (SIC) mode.

23. The method of claim 22, wherein the first threshold and the second threshold are based on the determination that the differential voltage is associated with the data operation mode or the SIC mode.

24. The method of claim 21, further including masking the first output voltage for a predetermined amount of time based on the select signal being the high voltage.
